(19) United States
(12) Patent Application Publication
(10) Pub. No.: US 2025/0286357 A1
(43) Pub. Date: Sep. 11, 2025

(54) ELECTRONIC CONTROL UNIT

(71) Applicant: Yazaki Corporation, Tokyo (JP)

(72) Inventors: Katsunori SATO, Shizuoka (JP); Koki Adachi, Shizuoka (JP)

(73) Assignee: Yazaki Corporation, Tokyo (JP)

(21) Appl. No.: 19/068,284

(22) Filed: Mar. 3, 2025

(30) Foreign Application Priority Data
Mar. 11, 2024 (JP) 2024-036602

(51) Int. Cl. H02G 3/16; H01R 9/24

(52) U.S. Cl. CPC H02G 3/16; H01R 9/2416

(57) ABSTRACT

In an electronic control unit, first terminal blocks on a routing board have an opening groove, which is penetrating in a first direction orthogonal to a normal direction of a routing surface, and inside of which a part of a second end of terminals is exposed. At least a part of an upper surface of the first terminal block is a routing region surface. A height position of the routing region surface from the routing surface is set higher than a bottom surface of the opening groove, and lower than a height position of a tip edge of the side wall by a distance that is larger than a dimension value of an outer diameter of the electric wires. A third width of the routing region surface in the first direction is set larger than the dimension value of the outer diameter of the electric wires.

### CROSS REFERENCE TO RELATED APPLICATION

The present application is based on, and claims priority from the Japanese Patent Application No. 2024-036602, filed on Mar. 11, 2024, the entire contents of which are incorporated herein by reference.

### TECHNICAL FIELD

The present disclosure relates to an electronic control unit.

### BACKGROUND

Conventionally, vehicles such as automobiles are equipped with an electronic control unit used for controlling various functions. In general, the electronic control unit includes a substrate on which electronic components are mounted. As an example of such a substrate, JP 2002-58129 A discloses a technology related to an electrical connection box including a wiring board having a plurality of reinforcing projections for supporting male terminals for fuse connections.

### SUMMARY OF THE INVENTION

On a substrate such as a wiring board disclosed in JP 2002-58129 A, a configuration in which an electric wire is connected to a terminal having one end joined to the substrate can also be considered. When a plurality of electric wires are routed on a substrate, a routing board arranged in parallel with the substrate is further provided, a plurality of electric wires are routed on the routing board, and end portions of the electric wires may be connected to a part of a terminal exposed on the routing board in advance. However, when, for example, a plurality of terminals exposed on the routing board are randomly arranged, and a large number of electric wires are intermingled on a routing board, there is room for improvement in order to increases degrees of freedom for wiring.

An object of the present disclosure is to provide an electronic control unit which increases degrees of freedom for wiring.

An electronic control unit according to an aspect of an embodiment includes a plurality of terminals; a plurality of electric wires having a first end portion connected to one end of the plurality of terminals; and a routing board for routing the plurality of electric wires introduced from outside, the routing board including a base having a routing surface facing the plurality of electric wires that are routed; a side wall provided on an edge of the base and projecting in a normal direction of the routing surface; and a plurality of terminal blocks provided on the routing surface; in which the terminal blocks have an opening groove, which is penetrating in a first direction orthogonal to the normal direction of the routing surface, and inside of which a part of the end of the terminals is exposed; at least a part of an upper surface of at least one of the terminal blocks is a routing region surface crossing in a second direction orthogonal to the normal direction of the routing surface and the first direction; a height position of the routing region surface from the routing surface is set higher than a bottom surface of the opening groove, and lower than a height position of a tip edge of the side wall by a distance that is larger than a dimension value of an outer diameter of the electric wires, and a width of the routing region surface in the first direction is set larger than the dimension value of the outer diameter of the electric wires.

According to the configuration above, it is possible to provide an electronic control unit, inside of which degrees of freedom for wiring are increased.

### BRIEF DESCRIPTION OF THE DRAWINGS

FIG. 1 is a perspective view of an electronic control unit according to one embodiment.

FIG. 2 is a perspective view of a circuit unit included in the electronic control unit.

FIG. 3 is an enlarged perspective view of electric wire connections corresponding to part III of FIG. 2.

FIG. 4 is a plan view of a circuit unit including an example of wiring on a routing board.

FIG. 5 is an enlarged plan view of the electric wire connections corresponding to part V in FIG. 4.

FIG. 6 is a side view of the electric wire connections corresponding to a cross section VI-VI in FIG. 5.

FIG. 7 is a cross-sectional view of the electric wire connections corresponding to a cross section VII-VII in FIG. 5.

FIG. 8 is a side view of the electric wire connections corresponding to a cross section VIII-VIII in FIG. 5.

FIG. 9 is a cross-sectional view of the electric wire connection corresponding to a cross section IX-IX in FIG. 5.

FIG. 10 is a side view of another example of the wire connections illustrated in accordance with FIG. 6.

FIG. 11 is a side view of another example of the wire connections illustrated in accordance with FIG. 8.

### DETAILED DESCRIPTION OF THE INVENTION

Hereinafter, an electronic control unit according to one embodiment will be described in detail with reference to the drawings. Hereinafter, the term “electronic control unit” will be abbreviated as “ECU.” The dimensional ratios in the drawings are exaggerated for the sake of explanation and may differ from the actual ratios.

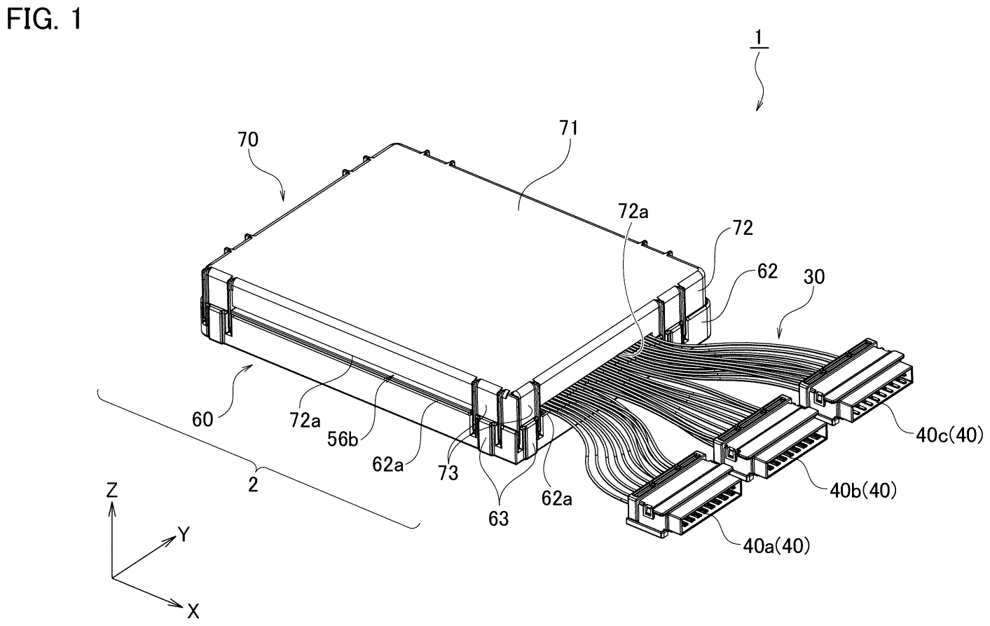

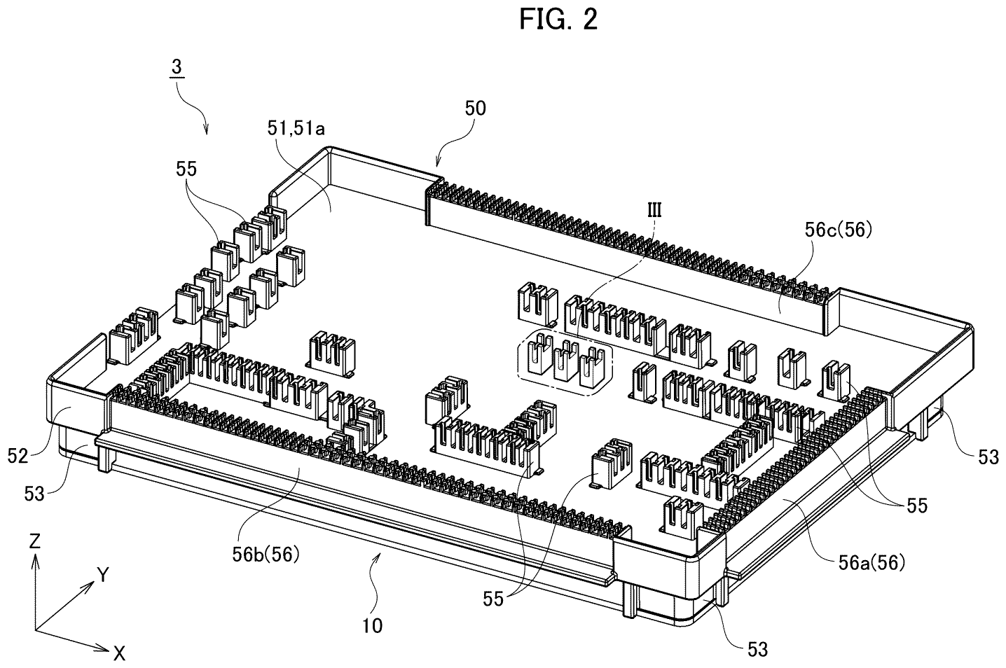

FIG. 1 is a perspective view of an ECU 1 according to one embodiment. FIG. 2 is a perspective view of a circuit unit 3 included in the ECU 1.

The ECU 1 is mounted in a vehicle such as an automobile, and controls various functions. The ECU 1 includes a substrate 10, a plurality of terminals 20, a plurality of electric wires 30, a connector 40, a routing board 50, a first cover 60, and a second cover 70.

Here, in the present embodiment, a unit including the substrate 10, the plurality of terminals 20, a part of the plurality of electric wires 30, the routing board 50, the first cover 60, and the second cover 70 is denoted as “main body 2.” A unit consisting of the substrate 10, the plurality of terminals 20, the plurality of electric wires 30, the connector 40, and the routing board 50 is denoted as “circuit unit 3.”

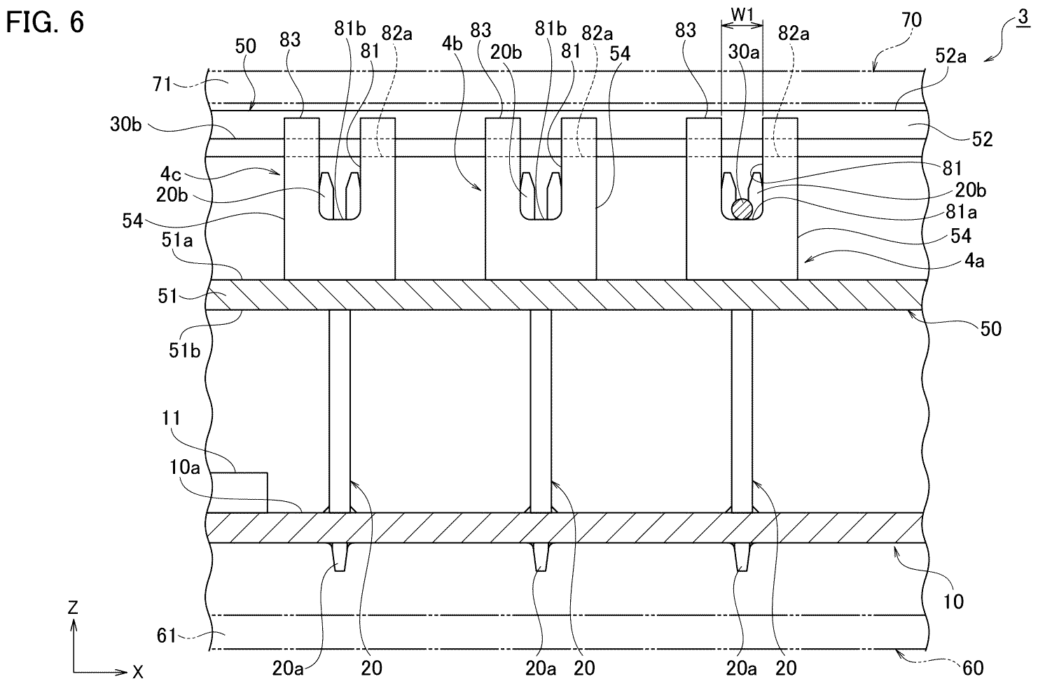

The substrate 10 is, for example, a printed circuit board (PCB) on which a plurality of electronic components 11 (see FIG. 6, for example.) are mounted in advance. Examples of the plurality of electronic components 11 include a CPU (Central Processing Unit) and a memory. In the present embodiment, the substrate 10 is regarded as a substantially rectangular flat plate which is parallel to a virtual XY plane defined by an X direction and a Y direction orthogonal to each other, and which has two ends in the X direction and two ends in the Y direction.

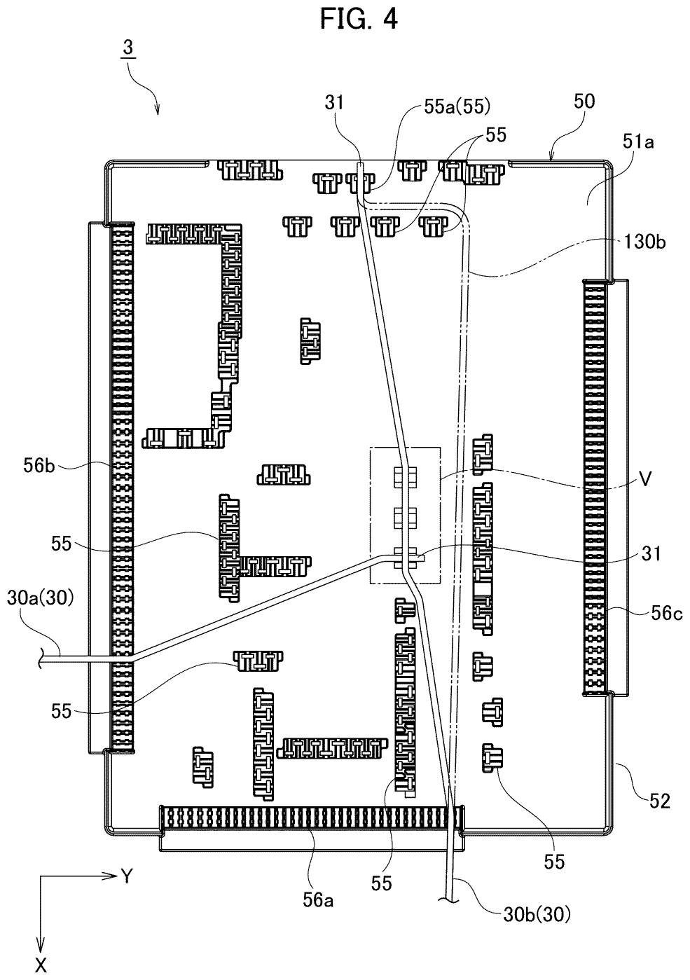

The terminals 20 electrically connect one of the electric wires 30 to a predetermined circuit on the substrate 10. The terminals 20 are a flat, rod-shaped metal member. Each of the terminals 20 has a first end 20a which is one end, and a second end 20b which is the other end opposite to the first end 20a (see FIG. 6, for example). The first end 20a is connected to a predetermined circuit on the substrate 10. In the present embodiment, since the substrate 10 is regarded as a flat plate parallel to the XY plane, the terminals 20 are each arranged on a mounting surface 10a (see FIG. 6, for example) so as to project in a Z direction orthogonal to both the X and Y directions. The second end 20b connects a first end portion 31 (see FIG. 4) of one of the electric wires 30. The second end 20b includes, for example, two protruding pieces parallel to each other, and a core wire of the electric wires 30 is clamped between the two protruding pieces, so that the first end portion 31 can be easily connected. At least a part of the second end 20b is supported by a first terminal block 54 or a second terminal block 55. At least a part of the second end 20b supported by the first terminal block 54 or the like is exposed through an opening groove 81 on a routing surface 51a of a base 51.

The electric wires 30 each electrically connect the connector 40 and one of the terminals 20. The electric wires 30 are electric wires in which a core wire as a conductor, is coated with an insulator. Each of the electric wires 30 has the first end portion 31 which is one end, and a second end portion 32 which is the other end opposite to the first end portion 31. As described above, the first end portion 31 is connected to the second end 20b of the terminals 20. The second end portion 32 is connected to the connector 40. In both of the first end portion 31 and the second end portion 32, a part that actually comes into contact with the second end 20b or the connector 40 is a core wire portion partially exposed by removing the insulator.

The connector 40 is connected to an external connector (not illustrated) that is provided to an object to which the ECU 1 is attached. In the present embodiment, the ECU 1 includes, as an example, three connectors 40, that is, a first connector 40a, a second connector 40b, and a third connector 40c. The second end portion 32 of each of the electric wires 30 is connected to one of the first connector 40a, the second connector 40b, and the third connector 40c. The connectors 40 are not directly provided on the substrate 10, but are connected to the main body 2 of the ECU 1 only through the electric wire wires 30.

The routing board 50 routes each of the electric wires 30 while connecting the first end portion 31 to the terminals 20 corresponding to each of the electric wires 30 inside the main body 2. The routing board 50 is made of, for example, a synthetic resin, and is a flat member arranged in parallel with the substrate 10. Since the routing board 50 is maintained in a stacked position with respect to the substrate 10, it may also be called a “wiring layer.” The routing board 50 has the base 51, a side wall 52, a pedestal 53, at least one first terminal block 54 (see FIG. 6, for example.), a plurality of second terminal blocks 55, and electric wire inlets 56.

The base 51 is a plate facing the substrate 10 in the Z direction. The planar shape of the base 51 is equivalent to that of the substrate 10. One surface of the base 51 is the routing surface 51a on which a part of each of the electric wires 30 is wired. A normal direction of the routing surface 51a is in the Z direction. The other surface of the base 51 is on a side opposite to the routing surface 51a, and is a back surface 51b facing the substrate 10 (See FIG. 6, for example.).

The side wall 52 is continuous with an edge of the base 51, and protrudes in the Z direction, that is, in the normal direction of the routing surface 51a, to surround the routing space on the routing surface 51a. However, the side wall 52 is not in the form of a frame surrounding entire four sides in the present embodiment, but is continuous with at least one of the electric wire inlets 56.

The pedestal 53 is continuous with the edge of the base 51, and protrudes in the Z direction to be at least partly in contact with an outer edge of the mounting surface 10a of the substrate 10. Thus, a constant distance between the base 51 and the substrate 10 is maintained.

The first terminal blocks 54 and the second terminal blocks 55 are provided on the routing surface 51a, and support the terminals 20 with the second end 20b thereof being exposed. The arrangement of the terminals 20 depends on the circuit configuration of the mounting surface 10a of the substrate 10. Therefore, the arrangement of the first terminal blocks 54 and the second terminal blocks 55 is also determined based on the circuit configuration of the substrate 10.

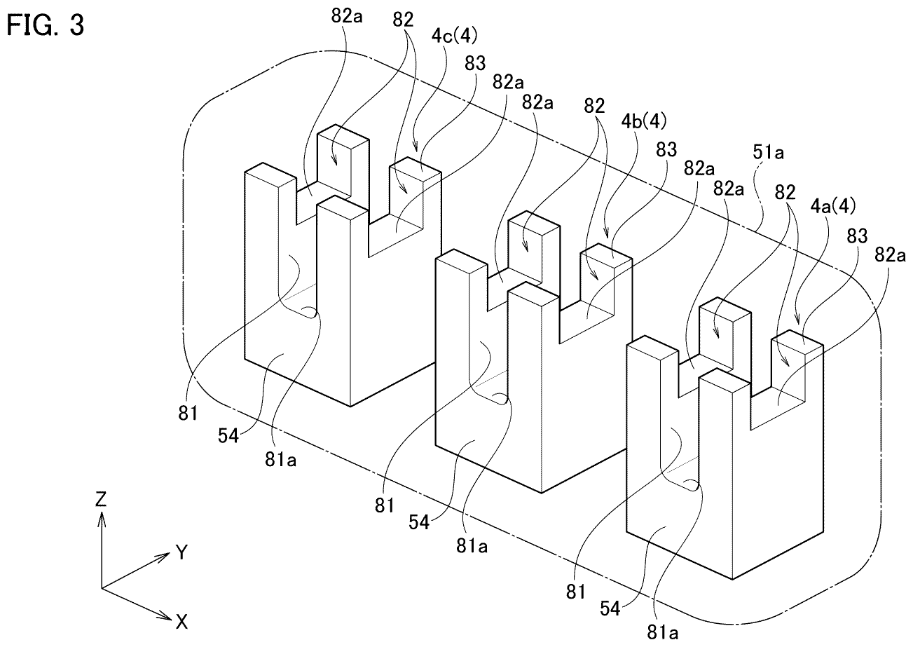

FIG. 3 is an enlarged perspective view of electric wire connections 4 corresponding to part III of FIG. 2. Here, the electric wire connections 4 refer to components in which the electric wires 30 are connected to the second end 20b of the terminals 20 in the first terminal blocks 54 or the second terminal blocks 55.

The first terminal blocks 54 are terminal blocks having a routing area surface 82a on at least a part of a first upper surface 83. In the present embodiment, as an example, it is assumed that three terminals 20 are present as the first terminals, and in addition. The first terminal blocks 54 have an opening groove 81, inside of which a part of the second end 20b is exposed. For each of the electric wires 30, a part of the first end portion 31 is inserted into the opening groove 81 that is predetermined, so that the core wire of the first end portion 31 is connected to the second end 20b. Hereinafter, the three electric wire connections 4 including the first terminal blocks 54 are referred to as a first electric wire connection 4a, a second electric wire connection 4b, and a third wire connection 4c. The first electric wire connection 4a, the second electric wire connection 4b, and the third wire connection 4c are lined up in a direction opposite to the X direction. The specific configuration of the electric wire connections 4 including the first terminal blocks 54 will be described in detail below.

The second terminal blocks 55 are terminal blocks with no surface, such as the routing region surface 82a, on an upper surface. In other words, the shape of the second terminal blocks 55 is the same as that of the first terminal blocks 54 except that it does not have an electric wire passage groove 82 including the routing region surface 82a as a bottom surface. It should be noted that the second terminal blocks 55 may have a shape in which a plurality of second terminal blocks 55 supporting the second end of one of the terminals 20 are integrated in parallel and continuously.

In this embodiment, among the plurality of terminal blocks on the routing surface 51a, three first terminal blocks 54 are present, and terminal blocks other than the first terminal blocks 54 are the second terminal blocks 55. However, among the plurality of terminal blocks, the number of the first terminal blocks 54 may be larger than the number of the second terminal blocks55. Furthermore, all of the plurality of terminal blocks may be the first terminal blocks 54. In other words, the presence of the second terminal blocks 55 is not essential.

The electric wire inlets 56 introduce the electric wires 30 onto the routing surface 51a of the base 51 from the outside of the routing board 50 while supporting a part of the electric wires 30. At least one of the electric wire inlets 56 is provided as a convex portion at an outer edge of the routing board 50 and on the routing surface 51a. In the present embodiment, as an example, three electric wire inlets 56 are present: a first electric wire inlet 56a extending in the Y direction, and a second electric wire inlet 56b and a third electric wire inlet 56c, each extending in the X direction. When routing the electric wires 30, not necessarily all of the electric wire inlets 56 are necessarily to be used. FIG. 1 illustrates, as an example, a configuration in which all the electric wires 30 are pulled into the body 2 from the connector 40 only through the first electric wire inlet 56a.

The first cover 60 and the second cover 70 are combined with each other to accommodate at least the substrate 10, the plurality of terminals 20, and the routing board 50 included in the circuit unit 3. The first cover 60 and the second cover 70 may be made of a synthetic resin or metal, for example.

The first cover 60 is a cover to be assembled from a side facing the substrate 10. The first cover 60 has a first flat plate 61 (see FIG. 6) covering the substrate 10 and a first frame 62 continuous with an edge of the first flat plate 61. The first frame 62 projects in the Z direction in which is the first frame 62 is assembled with respect to the second cover 70, so as to surround the substrate 10, for example. A part of a first tip edge 62a of the first frame 62 is close to the electric wire inlets 56 of the routing board 50 in a non-contact manner.

The second cover 70 is a cover to be assembled from a side facing the routing surface 51a of the routing board 50. The second cover 70 has a second flat plate 71 (see FIG. 6) covering the routing board 50, and a second frame 72 continuous with an edge of the second flat plate 71. The second frame 72 projects in a direction opposite to the Z direction, which is the direction to be assembled with respect to the first cover 60, so as to surround at least a part of the routing board 50, for example. A part of a second tip edge 72a of the second frame 72 is close to the electric wire inlets 56 of the routing board 50 in a non-contact manner. A part of an area between the first tip edge 62a of the first frame 62 of the first cover 60 and the second tip edge 72a of the second frame 72 of the second cover 70 is an open area through which the plurality of electric wires 30 pass inside and outside the main body 2.

The first cover 60 has a plurality of first locking portions 63 in the first frame 62. On the other hand, the second cover 70 has a plurality of second locking portions 73 in the second frame 72. The second cover 70 is combined with the first cover 60 by engaging the second locking portions 73 with the first locking portions 63.

Next, a specific configuration of the electric wire connections 4 including the first terminal blocks 54 will be described.

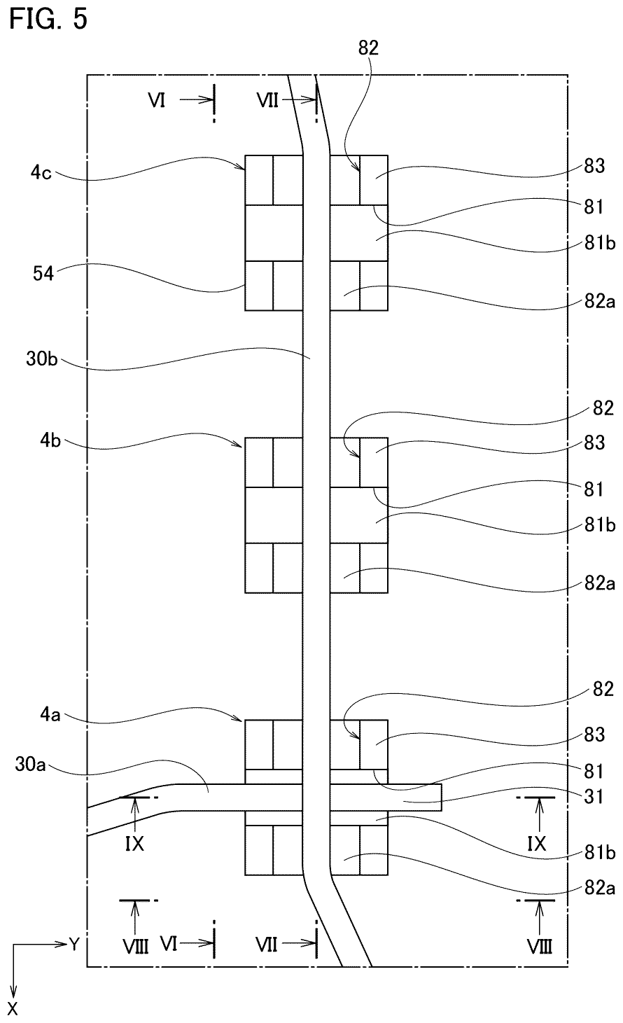

FIG. 4 is a plan view of the circuit unit 3 including an example of wiring on the routing board 50. FIG. 5 is an enlarged plan view of the electric wire connections 4 including the first terminal blocks 54 corresponding to part V in FIG. 4.

Here, although a large number of the electric wires 30 can actually be wired in the routing board 50, only two electric wires 30, the first electric wire 30a and the second electric wire 30b, will be exemplified below for the sake of simplicity.

The first electric wire 30a is an example of the electric wires 30 pulled into the main body 2 from a connector (not illustrated) similar to the connector 40 through the second electric wire inlet 56b. The first electric wire 30a is linearly wired from the second electric wire inlet 56b toward the first electric wire connection 4a on the routing surface 51a, for example, passing through gaps in the plurality of second terminal blocks 55. The first end portion 31 of the first electric wire 30a is connected to the second end 20b of the terminals 20 located in the first electric wire connection 4a.

The second electric wire 30b is an example of the electric wires 30 pulled into the main body 2 from the connector 40 through the first electric wire inlet 56a. The second electric wire 30b is linearly routed from the first electric wire inlet 56a to the second end 20b of the terminals 20 supported by one of the second terminal blocks 55, for example, passing through gaps in the plurality of second terminal blocks 55 on the routing surface 51a. Hereinafter, the second terminal block 55 supporting the second end 20b to which the first end portion 31 of the second electric wire 30b is connected is referred to as a “connection terminal block 55a” for convenience. The connection terminal block 55a is provided in the vicinity of another side wall 52 opposed in the X direction to the side wall 52 in which the first electric wire inlet 56a is provided.

The second electric wire 30b passes through the electric wire passage groove 82 formed in the first terminal block 54 included in each of the first electric wire connection 4a, the second electric wire connection 4b, and the third electric wire connection 4c. The second electric wire 30b passes above the first electric wire 30a connected to the first electric wire connection 4a. Here, the “above” with respect to each member refers to an area corresponding to an upper side when the routing surface 51a is a horizontal plane, and the normal direction of the routing surface 51a is from bottom to top.

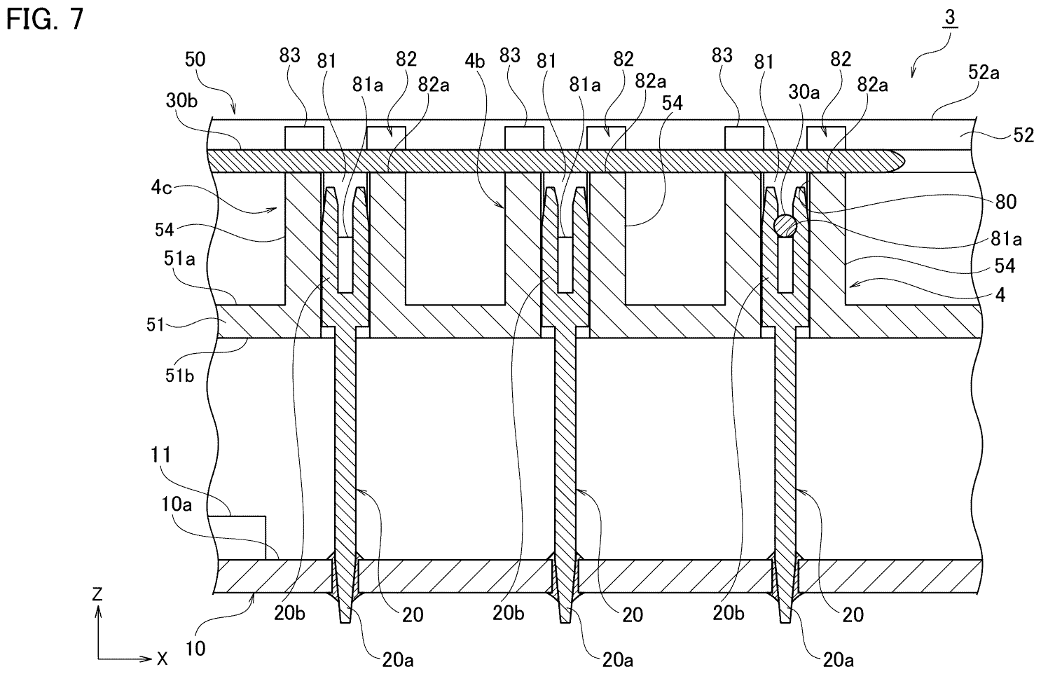

FIGS. 6 and 7 are views of the first electric wire connection 4a, the second electric wire connection 4b, and the third electric wire connection 4c as viewed in the Y direction. FIG. 6 is a side view of the electric wire connections 4 corresponding to a cross section VI-VI in FIG. 5. FIG. 7 is a cross-sectional view of the electric wire connections 4 corresponding to a cross section VII-VII in FIG. 5. The cross section in FIG. 7 is in an XZ plane passing through an intermediate position in a thickness direction corresponding to the Y direction of the terminals 20 supported by the first terminal blocks 54.

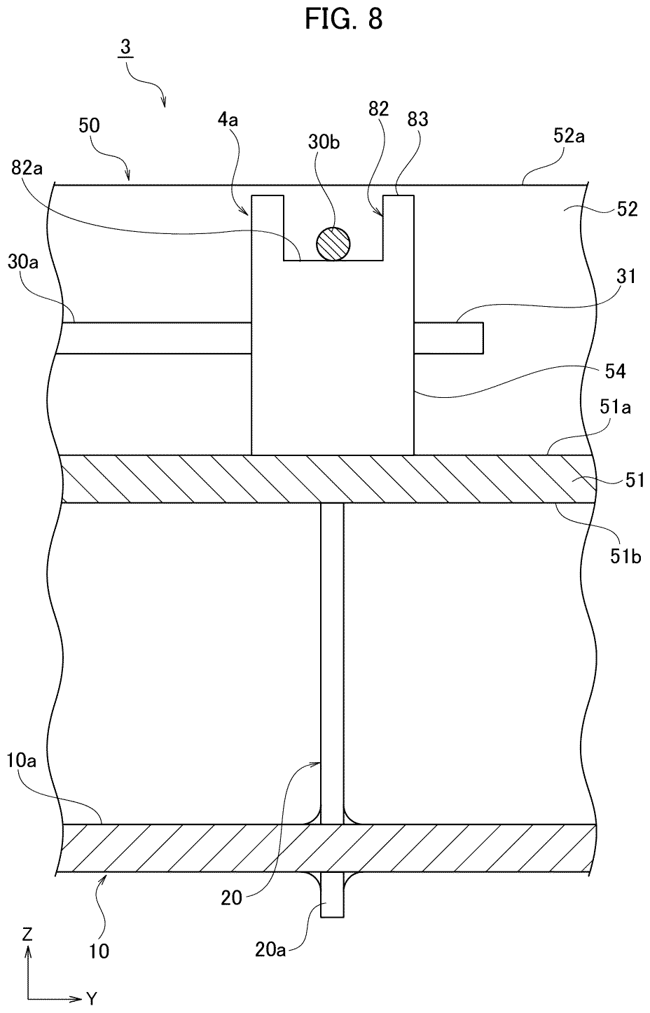

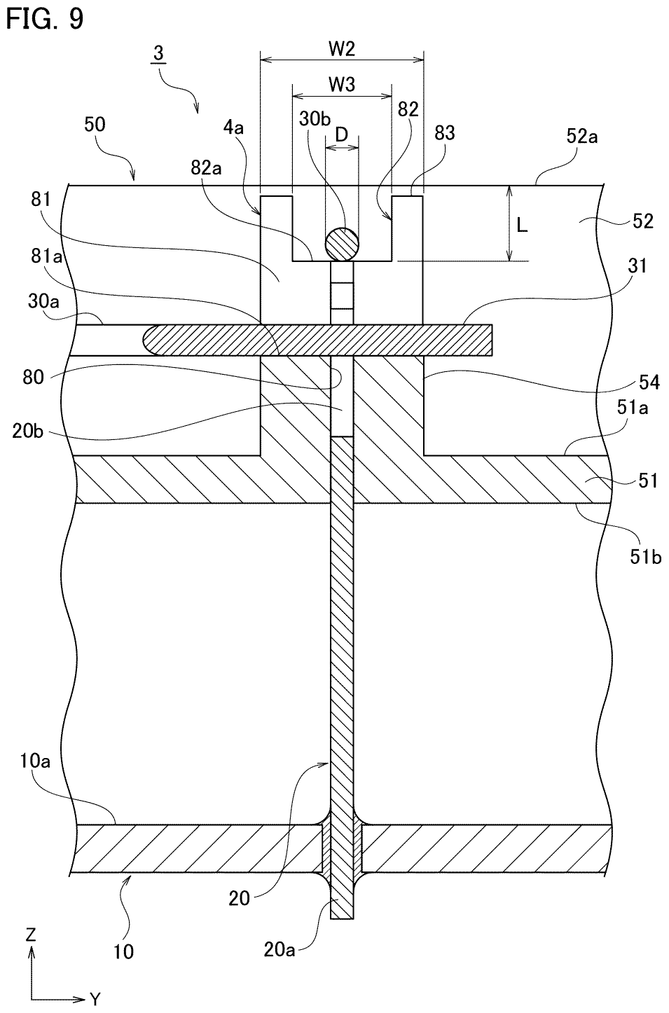

FIGS. 8 and 9 are views of the first electric wire connection 4a viewed in the negative X direction. FIG. 8 is a side view of the first electric wire connection 4a corresponding to a cross section VIII-VIII in FIG. 5. FIG. 9 is a cross-sectional view of the first electric wire connection 4a corresponding to a cross section IX-IX in FIG. 5. The cross section in FIG. 9 is in the YZ plane passing through an intermediate position in a width direction corresponding to the X direction of the terminals 20 supported by the first terminal blocks 54.

The three electric wire connections 4 including the first terminal blocks 54 have the same configuration. Therefore, the first electric wire connection 4a will be mainly described with respect to the shape or the like.

First, as described above, the second ends 20b of the terminals 20 are supported by the first terminal blocks 54 so that at least a part thereof is exposed on the routing surface 51a , thereby connecting the electric wires 30 by clamping the core wires of the electric wires 30 between the two protruding pieces above the routing surface 51a.

The first terminal blocks 54 are provided for each of the terminals 20 in the present embodiment, and therefore, three first terminal blocks 54 are present for the first electric wire connection 4a, the second electric wire connection 4b, and the third electric wire connection 4c. As in the example of the second terminal blocks 55 described above, the first terminal blocks 54 may have a shape such that the three first terminal blocks 54 supporting the second end 20b of each of the terminals 20 are integrated in parallel and continuously.

The overall schematic shape of the first terminal blocks 54 is a rectangular parallelepiped whose one end is continuous with the routing surface 51a of the base 51. Hereinafter, an upper surface of the first terminal block 54 refers to a surface of the first terminal block 54 that is located on an upper side in the normal direction of the routing surface 51a corresponding to the Z direction, and faces the second flat plate 71 of the second cover 70 in the Z direction when the ECU 1 is assembled. When the ECU 1 is assembled, the first upper surfaces 83 face the second flat plate 71 of the second cover 70 in the Z direction, as illustrated in FIG. 6. The first terminal blocks 54 have a terminal through-hole 80, an opening groove 81, and an electric wire passage groove 82.

The terminal through-hole 80 accommodates the second end 20b of the terminals 20. The terminal through-hole 80 is penetrating in the Z direction in which the base 51 faces the substrate 10. One opening of the terminal through-hole 80 is located on a bottom surface 81a of the opening groove 81. The other opening of the terminal through-hole 80 is located on the back surface 51b of the base 51 in this embodiment. In this embodiment, the direction (hereinafter referred to as “clamping direction”) in which the second end 20b clamps the first electric wire 30a is in the X direction. Therefore, in order to stably support the second end 20b, a part of walls defining the terminal through-hole 80 may be a pair of fitting groove portions which face each other in the X direction in accordance with the clamping direction to fit a part of the second end 20b.

The opening groove 81 is a groove which is opened at the first upper surface 83 and is penetrating in the first direction orthogonal to the normal direction of the routing surface 51a. In this embodiment, the first direction corresponds to the Y direction. The opening groove 81 communicates with the terminal through-hole 80 and exposes a part of the second end 20b of the terminals 20 inside. In the opening groove 81, it is necessary to satisfy the condition that the first end portion 31 of the first electric wire 30a is introduced in the first direction, and the second end 20b clamps and connects the first end portion 31 that has been introduced. Therefore, a first width W1 of the opening groove 81 in the second direction along the clamping direction is set larger than a dimension value of the outer diameter D of the first electric wire 30a, as illustrated in FIG. 6. On the other hand, a second width W2 in the first direction orthogonal to the first width W1 in the opening groove 81 is the same as the width of the first terminal block 54 in the first direction.

The opening groove 81 has the bottom surface 81a which is separated from the height position of the first upper surface 83 in the direction opposite to the normal direction of the routing surface 51a, and is separated from the height position of the routing surface 51a in the normal direction. The bottom surface 81a is substantially parallel to the first upper surface 83 and the routing surface 51a. The height position of the bottom surface 81a may be set so that the second end 20b of the terminals 20 connects the first end portion 31 at a desired position when the first end portion 31 of the first electric wire 30a introduced into the opening groove 81 is in contact with the bottom surface 81a.

The electric wire passage groove 82 is a groove which is opened at the first upper surface 83, and is penetrating in the second direction orthogonal to the normal direction of the routing surface 51a. In this embodiment, the second direction corresponds to the X direction. The electric wire passage groove 82 allows a second electric wire 30b to pass, which is different from the first electric wire 30a connected to the terminals 20, supported by the first terminal block 54. Therefore, the electric wire passage groove 82 is formed to cross a part of the opening groove 81 in the first terminal block 54.

Further, the electric wire passage groove 82 has, as a bottom surface thereof, the routing region surface 82a which crosses the first terminal block 54 in the second direction. The routing region surface 82a is an end surface located opposite to a virtual end surface P in the Z direction, and it can be regarded as a part of the upper surface of the first terminal block 54.

The height position of the routing region surface 82a in the Z direction with respect to the routing surface 51a is set higher than the bottom surface 81a of the opening groove 81. Further, the height position of the routing region surface 82a is set to a position lower than the height position of a tip edge 52a of the side wall 52, by a distance L, as illustrated in FIG. 9. The distance L is larger than the dimension value of the outer diameter D of the electric wires 30.

A third width W3 in the first direction of the routing region surface 82a is set to be narrower than the second width W2, and larger than the dimension value of the outer diameter D of the electric wires 30, as illustrated in FIG. 9. Here, the third width W3 may have a dimension value more than twice the outer diameter D of the electric wires 30 so that the plurality of electric wires 30 can pass through the electric wire passage groove 82 at the same time.

Next, effects of the ECU 1 will be described.

The ECU 1 includes the plurality of terminals 20; the plurality of electric wires 30 having the first end portion 31 connected to one end of the plurality of terminals 20; and the routing board 50 for routing the plurality of electric wires 30 introduced from outside. The routing board 50 has the base 51 having the routing surface 51a facing the plurality of electric wires 30 that are routed; the side wall 52 provided on an edge of the base 51 and projecting in a normal direction of the routing surface 51a; and a plurality of terminal blocks provided on the routing surface 51a. The terminal blocks have an opening groove 81, which is penetrating in a first direction orthogonal to the normal direction of the routing surface 51a, and inside of which a part of the second end 20b of the terminals 20 is exposed. At least a part of an upper surface of terminal block 54, which is at least one of the terminal blocks, is a routing region surface crossing in a second direction orthogonal to the normal direction of the routing surface 51a and the first direction. The height position of the routing region surface from the routing surface 51a is set higher than the bottom surface 81a of the opening groove 81, and lower than the dimension value of the outer diameter D of the electric wires 30 from the height position of the tip edge 52a of the side wall 52. The third width W3 of the routing region surface in the first direction is set larger than the dimension value of the outer diameter D of the electric wires 30.

In addition, in the ECU 1, the first terminal block 54 may have the electric wire passage groove 82 allowing, for example, the second electric wire 30b to pass, which is different from, for example, the first electric wire 30a connected to the terminal 20 supported by the first terminal block 54. The routing region surface may be the routing region surface 82a which is a bottom surface of the electric wire passage groove 82.

In the example above, the normal direction of the routing surface 51a corresponds to the Z direction, the first direction corresponds to the Y direction, and the second direction corresponds to the X direction.

Here, as a comparative example, it is assumed that all of the first electric wire connection 4a, the second electric wire connection 4b, and the third electric wire connection 4c, which include the first terminal block 54 in the example above, includes the second terminal block 55 without the electric wire passage groove 82, instead of the first terminal block 54. According to the comparative example, the first electric wire 30a can be wired in the same wiring path as in the example above. However, the second terminal block 55 included in the first electric wire connection 4a does not have the electric wire passage groove 82, and closely faces the second flat plate 71 of the second cover 70 with an upper surface, so that the second electric wire 30b cannot pass above the second terminal block 55. Therefore, as illustrated in FIG. 4, a virtual electric wire 130b in place of the second electric wire 30b is routed on a wiring path that avoids a plurality of the second terminal blocks 55. In other words, the wiring path of the virtual electric wire 130b is assumed to be more complicated than that of the second electric wire 30b. Moreover, the length of the virtual electric wire 130b is assumed to be longer than that of the second electric wire 30b.

In the ECU 1 according to the present embodiment, all of the first electric wire connection 4a, the second electric wire connection 4b, and the third electric wire connection 4c includes the first terminal block 54 having the electric wire passage groove 82 provided to cross the opening groove 81. The height position of the routing region surface 82a, which is a bottom surface of the electric wire passage groove 82, is higher than the bottom surface 81a of the opening groove 81, and lower than the dimension value of the outer diameter D of the electric wires 30 from the height position of the tip edge 52a of the side wall 52. In addition, the third width W3 of the routing region surface 82a satisfies the condition that it is wider than the dimension value of the outer diameter D of the electric wires 30. Therefore, for example, if it is desired to route some of the electric wires 30, such as the second electric wire 30b, in a simple linear path, the electric wire passage groove 82 can be used as a routing region of the second electric wire 30b, so that interference with the first terminal blocks 54 is difficult to occur. Therefore, according to the ECU 1, the wiring freedom of the electric wires 30 can be increased. In particular, instead of the examples illustrated in the drawings, the wiring freedom of the electric wires 30 can be further increased by using the first terminal blocks 54 for all the terminal blocks provided on the routing surface 51a.

As described above, according to the present embodiment, it is possible to provide the ECU 1, inside of which the degrees of freedom for wiring are increased.

According to the ECU 1, the wiring path is simplified for each of the electric wires 30 by increasing the degrees of freedom for wiring, wire saving of the plurality of electric wires 30 is possible, and the main body 2 can be miniaturized or reduced in weight by increasing the wiring space on the routing board 50.

Furthermore, in the ECU 1, the electric wires 30 such as the second electric wire 30b passing through the electric wire passage groove 82 are prevent from moving in the first direction corresponding to a penetrating direction of the opening groove 81 by the electric wire passage groove 82. Therefore, according to the ECU 1, it is advantageous that the wiring paths of the plurality of electric wires 30 can be easily maintained in a desired state in the routing board 50.

Here, in the examples above with reference to the drawings, the routing region surface is assumed to be the routing region surface 82a which is the bottom surface of the electric wire passage groove 82. However, the embodiments are not limited thereto, and an entire top surface of the first terminal blocks 54 may be used as a routing region surface.

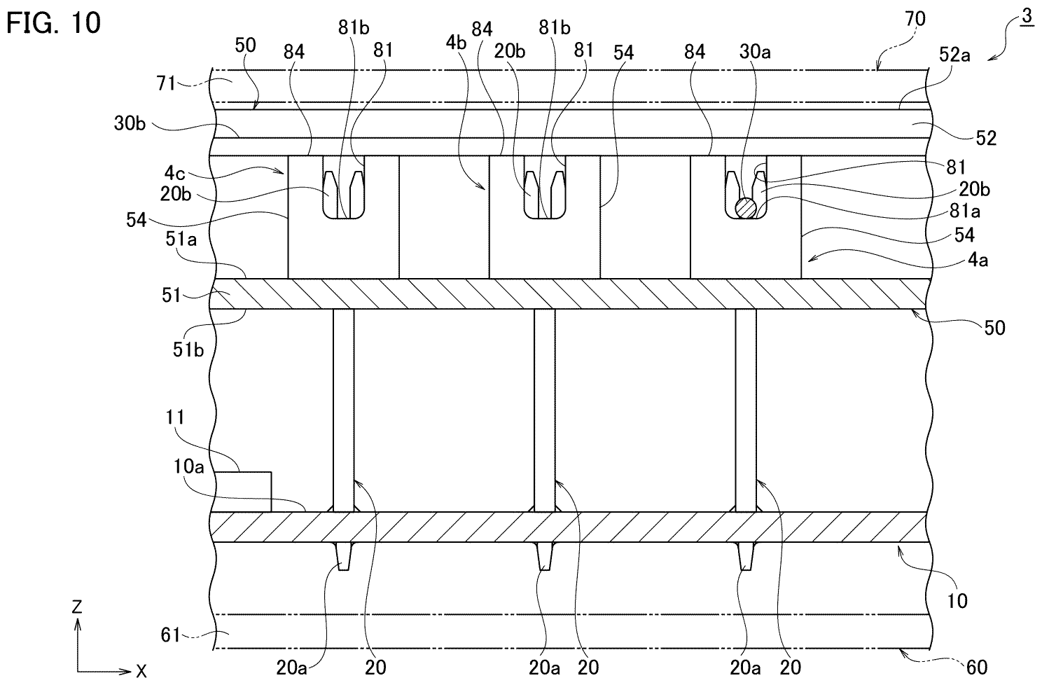

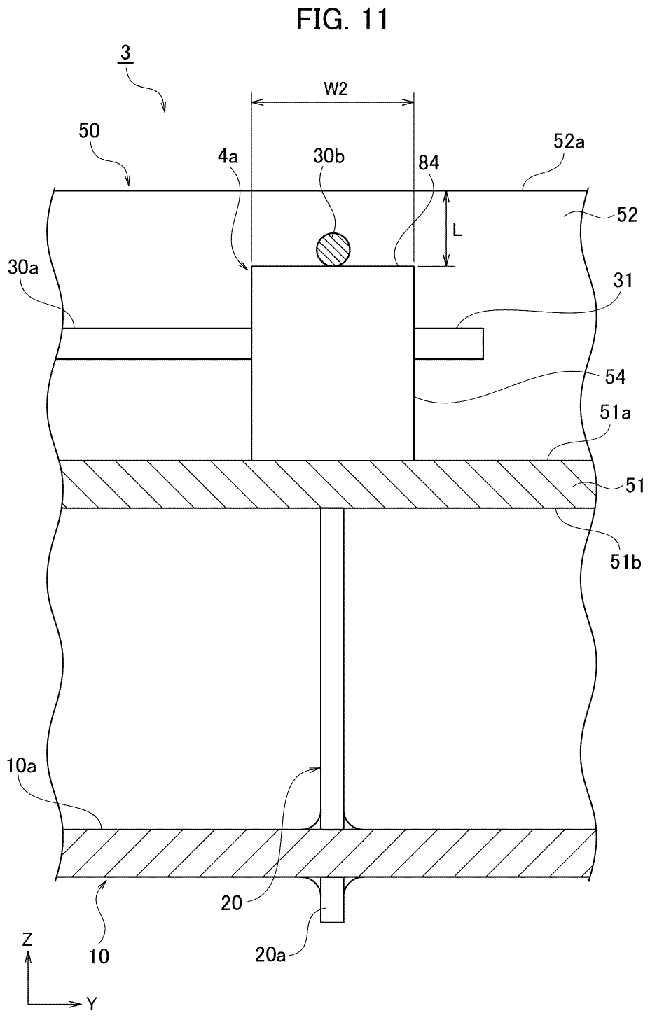

FIG. 10 is a side view of another example of the electric wire connections 4 illustrated in accordance with FIG. 6. FIG. 11 is a side view of another example of the electric wire connections 4 illustrated in accordance with FIG. 8.

In other examples of the electric wire connections 4 illustrated in FIGS. 10 and 11, the upper surface of the first terminal blocks 54 is a second upper surface 84 instead of the first upper surface 83. The height position of the second upper surface 84 in the normal direction with respect to the routing surface 51a is set to the height position of the routing area surface 82a when the first terminal block 54 has the electric wire passage groove 82. Therefore, according to the ECU 1 as described above, the electric wires 30 such as the second electric wire 30b can pass above the first terminal block 54 in the same way as the case including the first terminal block 54 having the electric wire passage groove 82, so that the degrees of freedom of wiring inside the ECU 1 can be increased.

Furthermore, the ECU 1 may include the connectors 40 to which the second end portion 32 opposite to the first end portion 31 of each of the electric wires 30 is connected.

In this ECU 1, the connectors 40 are only connected to the main body 2 via the plurality of electric wires 30, so that positions of the connectors 40 can be freely changed relative to the main body 2. Therefore, according to the ECU 1, it is possible to avoid, for example, the occurrence of troubles such as reduced space in a passenger compartment due to bulging of external electric wires around the main body 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

1. An electronic control unit comprising:
a plurality of terminals;
a plurality of electric wires having a first end portion connected to one end of the plurality of terminals; and
a routing board for routing the plurality of electric wires introduced from outside;
the routing board comprising:
a base having a routing surface facing the plurality of electric wires that are routed;
a side wall provided on an edge of the base and projecting in a normal direction of the routing surface; and
a plurality of terminal blocks provided on the routing surface;
wherein
the terminal blocks have an opening groove, which is penetrating in a first direction orthogonal to the normal direction of the routing surface, and inside of which a part of the end of the terminals is exposed;
at least a part of an upper surface of at least one of the terminal blocks is a routing region surface crossing in a second direction orthogonal to the normal direction of the routing surface and the first direction;
a height position of the routing region surface from the routing surface is set higher than a bottom surface of the opening groove, and lower than a height position of a tip edge of the side wall by a distance that is larger than a dimension value of an outer diameter of the electric wires; and
a width of the routing region surface in the first direction is set larger than the dimension value of the outer diameter of the electric wires.

2. The electronic control unit according to claim 1, wherein:
the terminal blocks have a wire passage groove allowing a second electric wire to pass, which is different from the electric wire connected to the terminals supported by the terminal blocks; and
the routing region surface is a bottom surface of the wire passage groove.

3. The electronic control unit according to claim 1, comprising connectors to which a second end portion opposite to the first end portion of each of the electric wires is connected.
